(19) United States
(12) Patent Application Publication
(10) Pub. No.: US 2010/0276192 A1
(43) Pub. Date: Nov. 4, 2010

(54) METHOD FOR REMOVING A STUB OF A VIA HOLE AND A PRINTED CIRCUIT BOARD DESIGNED BASED ON THE METHOD

(75) Inventors: CHIA-NAN PAI, Tu-Cheng (TW); SHOU-KUO HSU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/503,684

(22) Filed: Jul. 15, 2009

(30) Foreign Application Priority Data
Apr. 30, 2009 (CN) 200910302003.X

(51) Int. Cl. H05K 1/11; H05K 3/42

(52) U.S. Cl. 174/266; 29/852

(57) ABSTRACT

A method for removing a stub of a via hole includes copperizing a wall of a via hole in a top layer of a printed circuit board (PCB) if signal lines are located on the top layer of the PCB, and a wall of the via hole in a bottom layer of the PCB is not copperized. The method further includes connecting the top layer and the bottom layer of the PCB using a connection layer.

### BACKGROUND

1. Technical Field

Embodiments of the present disclosure relate to methods for designing a printed circuit board (PCB), and particularly to a method for removing a stub of a via hole and a PCB designed based on the method.

2. Description of Related Art

Via holes design is an important phase in the design of a printed circuit board (PCB). Generally, a stub of the via holes will be generated because the PCB has a plurality of layers (refer to FIG. 1).

There are two common methods for removing the stub of the via holes. A first method applies a technique of manufacturing buried via holes to remove the stub of the via holes. A second method applies a back-drilling technique to remove the stub of the via holes when the PCB has been produced. However, the above-mentioned two method will increase production costs, and the back-drilling technique is hard to perform.

### BRIEF DESCRIPTION OF THE DRAWINGS

FIG. 1 is a schematic diagram of one embodiment of a stub of a via hole in a printed circuit board (PCB);

FIG. 2 is a schematic diagram of one embodiment of a method for removing the stub of the via hole in a bottom layer of the PCB;

FIG. 3A is a graph of one embodiment of a simulation result of an impedance signal applying the PCB shown in FIG. 1;

FIG. 3B is an eye diagram of one embodiment of a simulation result of the via hole of the PCB shown in FIG. 1;

FIG. 4A is a graph of one embodiment of a simulation result of an impedance signal applying the method shown in FIG. 2; and

FIG. 4B is an eye diagram of one embodiment of a simulation result of the via hole of the PCB designed by the method shown in FIG. 2.

### DETAILED DESCRIPTION

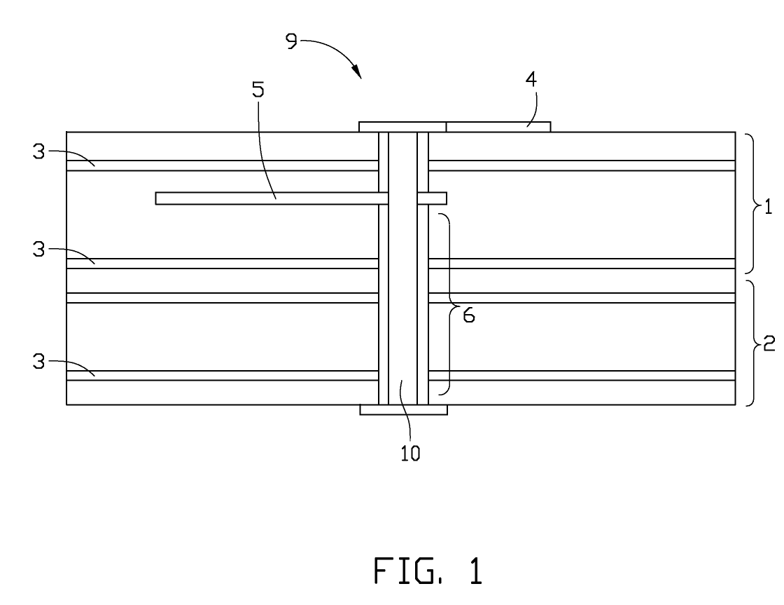

FIG. 1 is a schematic diagram of one embodiment of a stub 6 of a via hole 10 in a printed circuit board (PCB) 9. In one embodiment, the PCB 9 includes a top layer 1, a bottom layer 2, a ground layer/power layer 3, a micro-strip line 4, a strip line 5, and the stub 6 of the via hole 10. It may be understood that the embodiment of the PCB 9 as illustrated in FIG. 1 is exemplary and may include other components that will be explained further herein, such as a resistor and a capacitor. In one embodiment, the PCB 9 is located at a backplane of a storage device. The via hole 10 is used to transmit signals from the top layer 1 (e.g., the strip line 5) of the PCB 9 to the bottom layer 2 (e.g., the power layer 3) of the PCB 9.

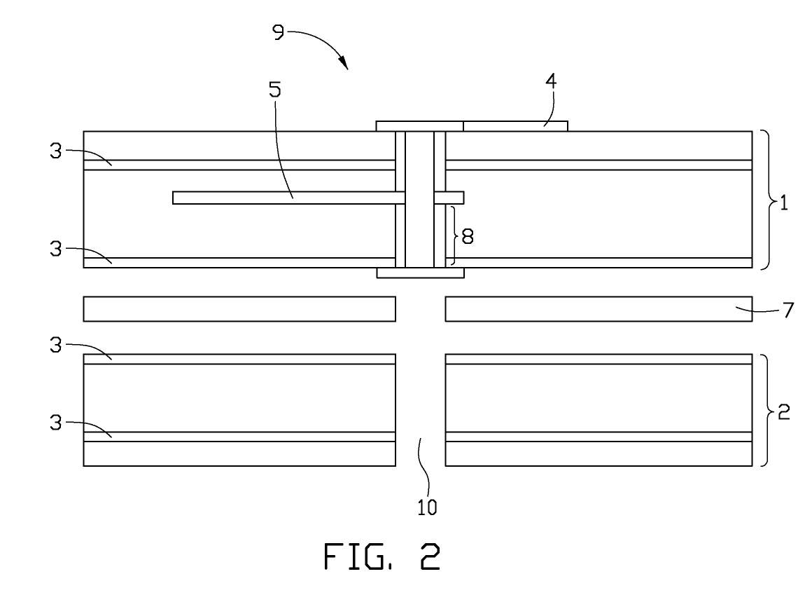

FIG. 2 is a schematic diagram of one embodiment of a method for removing the stub of the via hole 10 in the bottom layer 2 of the PCB 9. Firstly, a wall of the via hole 10 in the top layer 1 of the PCB 9 is copperized (i.e., performing a copper-plating process on the wall of the via hole 10) if signal lines (i.e., the micro-strip line 4 and the strip line 5) are located on the top layer 1 of the PCB 9, and a wall of the via hole 10 in the bottom layer 2 of the PCB 9 is not copperized. Secondly, the top layer 1 and the bottom layer 2 of the PCB 9 are connected via a connection layer 7. Then, the stub of the via hole 10 in the bottom layer 2 of the PCB 9 can be removed easily, so that production costs are reduced. A stub 8 of the via hole 10 in the top layer 1 of the PCB is kept. It may be understood that the stub 6 of the via hole 10 in FIG. 1 is smaller than the stub 8 of the via hole 10 in FIG. 2, and quality of signals transmitted by the via hole 10 in FIG. 2 is better than quality of signals transmitted by the via hole 10 in FIG. 1 (simulation results of the signals are shown below).

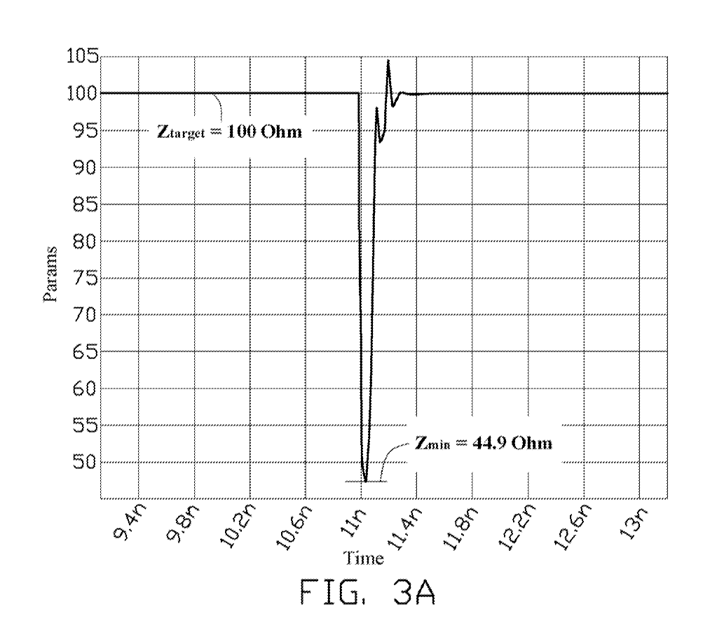

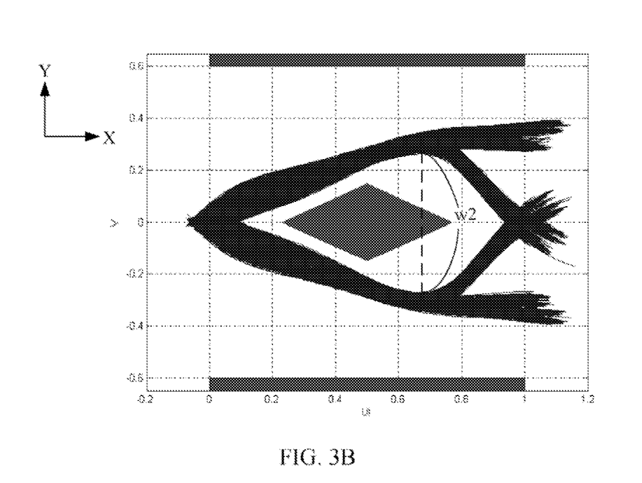

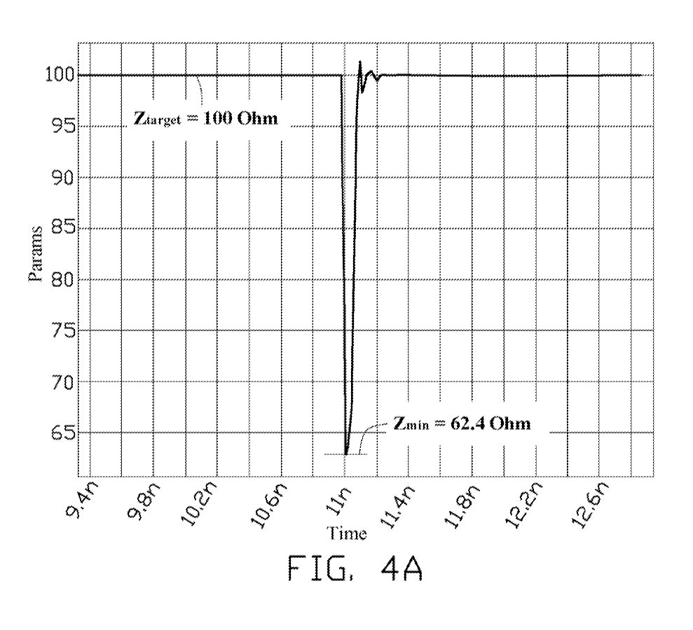

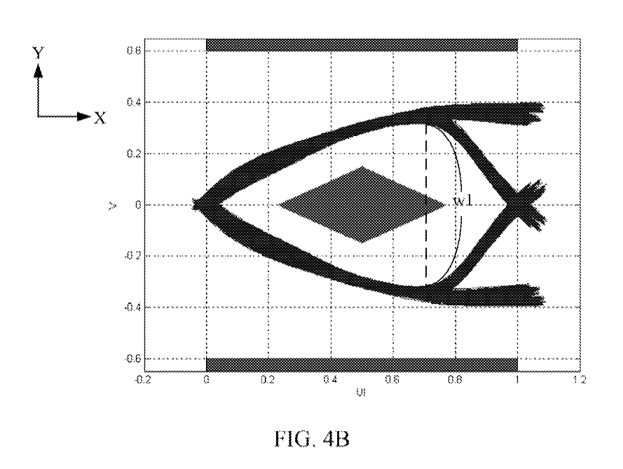

FIG. 3A is a graph of one embodiment of a simulation result of an impedance signal applying the PCB 9 shown in FIG. 1, and FIG. 4A is a graph of one embodiment of a simulation result of an impedance signal applying the method shown in FIG. 2. A maximum impedance Z_{target} in FIG. 3A is about 100 ohms, a minimum impedance Zₘᵢₙ in FIG. 3A is about 44.9 ohms, and a maximum impedance Z_{target} in FIG. 4A is about 100 ohms, a minimum impedance Zₘᵢₙ in FIG. 4A is about 62.4 ohms. Thus, a difference value between the maximum impedance and the minimum impedance in FIG. 3A is about 100 ohms−44.9 ohms=55.1 ohms, and a difference value between the maximum impedance and the minimum impedance in FIG. 4A is about 100 ohms−62.4 ohms=37.6 ohms. Because 37.6 ohms is less than 55.1 ohms, the quality of the impedance signal transmitted by the via hole 10 in FIG. 2 is better than the quality of the impedance signal transmitted by the via hole 10 in FIG. 1.

FIG. 3B is an eye diagram of one embodiment of a simulation result of the via hole of the PCB shown in FIG. 1, and FIG. 4B is an eye diagram of one embodiment of a simulation result of the via hole of the PCB designed based on the method shown in FIG. 2. Because a width of the eye diagram “w1” in FIG. 4B is greater than a width of the eye diagram “w2” in FIG. 3B, it may be understood that quality of signals transmitted by the via hole 10 in FIG. 2 is better than quality of signals transmitted by the via hole 10 in FIG. 1.

In other embodiment, if the signal lines (i.e., the micro-strip line 4 and the strip line 5) are located on the bottom layer 2 of the PCB 9, a method for removing the stub of the via hole 10 in the top layer 1 of the PCB 9 comprises the following steps. Firstly, a wall of the via hole 10 in the bottom layer 2 of the PCB 9 is copperized (i.e., performing a copper-plating process on the wall of the via hole 10), and a wall of the via hole 10 in the top layer 1 of the PCB 9 is not copperized. Secondly, the top layer 1 and the bottom layer 2 of the PCB 9 are connected via a connection layer 7 thereby the stub of the via hole 10 in the top layer 1 of the PCB 9 can be removed easily.

The present embodiments automatically remove the stub of the via hole 10 in the top layer 1 or the bottom layer 2 of the PCB 9, and the quality of signals transmitted by the via hole 10 still comply with guidelines of a simulation test.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A method for removing a stub of a via hole, the method comprising:
copperizing a wall of a via hole in a top layer of a printed circuit board (PCB) comprising signal lines located on a top layer of the PCB, wherein a wall of the via hole in a bottom layer of the PCB is not copperized; and
connecting the top layer and the bottom layer of the PCB using a connection layer.

2. The method according to claim 1, wherein the PCB is located at a backplane of a storage device.

3. The method according to claim 1, wherein the signal lines comprise a micro-strip line and a strip line.

4. The method according to claim 1, wherein the PCB further comprises a ground layer.

5. The method according to claim 1, wherein the PCB further comprises a power layer.

6. A method for removing a stub of a via hole, the method comprising:
copperizing a wall of a via hole in a bottom layer of a printed circuit board (PCB) comprising signal lines located on a bottom layer of the PCB, wherein a wall of the via hole in a top layer of the PCB is not copperized; and
connecting the top layer and the bottom layer of the PCB using a connection layer.

7. The method according to claim 6, wherein the PCB is located at a backplane of a storage device.

8. The method according to claim 6, wherein the signal lines comprise a micro-strip line and a strip line.

9. The method according to claim 6, wherein the PCB further comprises a ground layer.

10. The method according to claim 6, wherein the PCB further comprises a power layer.

11. A printed circuit board (PCB), comprising:
a top layer and a bottom layer;
a via hole with a wall located in the top layer and a wall located in the bottom layer, wherein the wall in the top layer is copperized if signal lines are located on a top layer and the wall in the bottom layer is not copperized, or the wall in the bottom layer is copperized if signal lines are located on a bottom layer and the wall in the top layer is not copperized; and
a connection layer operable to connect the top layer and the bottom layer of the PCB.

12. The PCB according to claim 11, wherein the PCB is located at a backplane of a storage device.

13. The PCB according to claim 11, wherein the signal lines comprise a micro-strip line and a strip line.

14. The PCB according to claim 11, further comprising a ground layer.

15. The PCB according to claim 11, further comprising a power layer.
